(19) United States
(12) Patent Application Publication
(10) Pub. No.: US 2005/0259465 A1
(43) Pub. Date: Nov. 24, 2005

(54) Nonvolatile memory apparatus

(75) Inventors: Satoshi Yoshida, Sunagawa (JP); Kunihiro Katayama, Chigasaki (JP); Shinsuke Asari, Akishima (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 11/128,289

(22) Filed: May 13, 2005

(30) Foreign Application Priority Data
May 20, 2004 (JP) 2004-150235

(51) Int. Cl. G11C 16/04

(52) U.S. Cl. 365/185.03

(57) ABSTRACT

In technology for enabling the replacement of part of an operating program of a controller by a modified program on a nonvolatile memory, the present invention prevents tampering and leak of storage information within the nonvolatile memory and the controller. At power-on reset, an encrypted alternative program, if present, is transferred from a nonvolatile memory to a volatile memory, and decrypted when actually executed. A long wait is not required until data processing by a data processor is enabled after the exit from the reset processing. Since the alternative program once decrypted is held in the volatile memory so as to be reusable, it does not need to be decrypted each time it is executed. Since the alternative program is encrypted, even if the nonvolatile memory is physically separated from the controller to illegally dump the alternative program, it is difficult to analyze the data.

### CROSS-REFERENCE TO RELATED APPLICATION

The present application claims priority from Japanese patent application No. 2004-150235 filed on May 20, 2004, the content of which is hereby incorporated by reference into this application.

### BACKGROUND OF THE INVENTION

The present invention relates to technology, in a memory apparatus having a controller and a nonvolatile memory, for replacing part of an operating program of the controller by a modified program on the nonvolatile memory, and technology suitably applied to e.g., a memory card.

Patent document 1 describes a method for easily modifying a program in ROM within a memory card controller in a memory card including the memory card controller and a flash memory. According to this method, a modification program is placed on the flash memory, and when power is turned on, the modification program is transferred to RAM within the memory card controller, and the modification program on the RAM is made executable in place of the program to be modified on the ROM.

To prevent tampering and leak of information stored on a flash memory, there is technology available to encrypt such information and store the encrypted information on a flash memory. Patent document 2 describes a flash memory card in which a personal information management application (requiring high security) that is stored in a flash memory and encrypted in a storage encryption processing part is decrypted by a storage key to read out it. This method makes it difficult to analyze stored data illegally dumped. Patent document 3 describes a memory card in which parts of application programs (bank dealing and credit settlement) for executing an IC card chip are encrypted and stored in a command processing module within a flash memory chip. Patent document 4 describes technology for recording highly confidential small-capacity data (important personal information) in a nonvolatile memory of a tamper resistant module (a device structure in which peeling a surface protection film would destroy lower wiring layers and make it impossible to disassemble circuits for analysis) and non-confidential data (applications executed by CPU) in a flash memory.
[Patent document 1] Japanese Published Unexamined Patent Application No. Hei 11(1999)-265283
[Patent document 2] Japanese Published Unexamined Patent Application No. 2003-256282
[Patent document 3] Japanese Published Unexamined Patent Application No. 2003-91704
[Patent document 4] Japanese Published Unexamined Patent Application No. 2002-229861(U.S. patent Ser. No. 10/062451)

### SUMMARY OF THE INVENTION

In technology for enabling the replacement of part of an operating program of a memory card controller by a modified program on a flash memory in a memory card including the memory card controller and the flash memory, the inventors studied about prevention against tampering and leak of the program and data within the memory controller as well as the modified program on the flash memory. Since the flash memory has its access terminals directly exposed to a chip, when the memory card is disassembled, the flash memory is more subject to tampering and leak of its stored information than an on-chip mask ROM of the memory card controller. In this case, as described in the patent documents 2 to 4, highly confidential data and programs should be stored in encryption in the flash memory. However, this is not sufficient for free modifications on programs within ROM of the memory card. Therefore, as described in the document 1, it is necessary to have a jump table for all programs within the ROM. In this case, however, it was recognized that programs and the like on the on-chip mask ROM of the memory card controller may be subjected to tampering and leak by illegal tampering and analysis to the jump table stored in the flash memory. For example, such an illegal access as to enable an external reference to highly confidential data held within a memory card controller may be made by tampering a jump table to bring the memory card controller into the execution of an illegal program. Also, an encrypted program transferred from the flash memory controller to the memory card controller at power-on reset must be decrypted before execution. In this case, performing the decryption together with the transfer to the RAM would require excessive long reset processing time when the program capacity is large.

An object of the present invention is, in technology for enabling the replacement of part of an operating program of a controller by a modified program on a nonvolatile memory, to provide a memory apparatus that can contribute to prevention against tampering and leak of the program and data within the controller as well as the modified program on the nonvolatile memory.

Another object of the present invention is, in technology for enabling the replacement of part of an operating program of a controller by a modified program on a nonvolatile memory, to prevent replacement processing from causing long delays of operation start after reset processing even when the capacity of the modified program is large.

The above-mentioned and other objects and novel characteristics of the present invention will become apparent from the description of this specification and the accompanying drawings.

The typical disclosures of the invention will be summarized in brief as follows.

[1] A memory apparatus includes a controller (3) that performs data processing and a first nonvolatile memory (4) that stores information so as to be rewritable under controller's control. The controller includes: a data processor (10); a second non-rewritable nonvolatile memory (11) accessed by the data processor; and a rewritable volatile memory (12) accessed by the data processor. The second nonvolatile memory has a processing program (PGM) of the data processor, and the first nonvolatile memory has a storage area (20) of an encrypted alternative program (SMDLk) for replacing part of the processing program. At power-on reset, the data processor transfers the encrypted alternative program, if present, to the volatile memory, and after the transfer, when executing the encrypted alternative program, decrypts the alternative program and stores the decrypted alternative program in the volatile memory so as to be reusable afterward.

According to the foregoing, at power-on reset, the encrypted alternative program, if present, is transferred to the volatile memory, and decrypted when actually executed. Accordingly, a long wait is not required until data processing by the data processor is enabled after the exit from the reset processing. Since the alternative program once decrypted is held in the volatile memory so as to be reusable, there is no troublesomeness of decrypting the alternative program each time it is executed. Since the alternative program is encrypted, even if the first nonvolatile memory is physically or electrically separated from the controller to illegally dump the alternative program, it is difficult to analyze the data.

It is desirable to decrypt the alternative program at the timing of its first execution after the transfer to the volatile memory. This is because the operating power may be turned off without even one execution of the alternative program. When a program from which high-speed processing speed is demanded is to be replaced, the power-on reset processing may be changed so that the alternative program is decrypted in advance during the power-on reset.

A description is made of how the above-mentioned processing program is executed using a jump table. For example, the second nonvolatile memory includes a first jump table (TBL) used when the processing program is executed, the first nonvolatile memory includes a storage area (21) of a second jump table (STBL) used when the processing program partially replaced by the alternative program is executed, and the storage area is used to store an encrypted second jump table. When transferring the encrypted alternative program after power-on reset is cleared to the volatile memory, the data processor decrypts the second jump table and stores the decrypted second jump table in the volatile memory so as to be usable afterward in place of the first jump table. By this arrangement, since the second jump table used for the execution of the processing program modified by the alternative program is stored in encryption in the first nonvolatile memory, even if the first nonvolatile memory can be physically or electrically separated from the memory card controller to illegally dump the jump table, it is difficult to analyze its contents or tamper the contents for illegal purposes. If the jump table could be tampered to bring the controller into the execution of an illegal program, such an illegal access as to enable an external reference to highly confidential data within the controller could be performed.

As a concrete embodiment of the present invention, the second nonvolatile memory has a write control program (MDL (PM ER)) that writes the alternative program and the second jump table respectively encrypted to the first nonvolatile memory. Even when a memory apparatus is mounted in an application system, the program and the jump table can be easily updated.

As a concrete embodiment of the present invention, a decryption processing program performs decryption by using a decryption operation module (hardware). The decryption processing program may perform the whole of processing.

As a concrete embodiment of the present invention, the jump table is rewritten to control the switching between the activation of the decryption processing program and the activation of the alternative program. Specifically, the second jump table includes a first table area (31) referred to in the processing program and a second table area (32) referred to in the decryption processing program, the location address information of the decryption processing program is stored in a first reference area (33) allocated to refer to the location address information of the alternative program in the first table area, and the location address information of the alternative program allocated to the first reference area is stored in a second reference area (34) corresponding to the first reference area in the second table area. By referring to the address information held in the first reference area and executing the decryption processing program located in the address, the data processor acquires an alternative program from an address of the address information in the corresponding second reference area, decrypts the acquired alternative program, and changes the address information held in the first reference area to the address information held in the corresponding second area. By this processing, the alternative program can be decrypted at the first execution timing, and afterward the decrypted alternative program can be directly executed.

The data processor can access the second nonvolatile memory and the volatile memory at random according to address signals. File access can be made to the first nonvolatile memory in units of logical sectors. The controller has a host interface complying with a prescribed memory card standard.

[2] A description is made of the decryption of an encoded jump table. The memory apparatus includes a controller that performs data processing, and a first nonvolatile memory that stores information so as to be rewritable under controller's control. The controller includes: a data processor; an unrewritable second nonvolatile memory accessed by the data processor; and a rewritable volatile memory accessed by the data processor. The second nonvolatile memory holds a processing program of the data processor, and a first jump table used when the processing program is executed. The first nonvolatile memory includes a storage area of an alternative program to replace part of the processing program, and a storage area of a second jump table used when the alternative program is executed. The storage area is used to store the second encryption jump table. At power-on reset, the data processor transfers the encrypted alternative program, if present, to the volatile memory, decrypts the second jump table, and stores the decrypted second jump table in the volatile memory so as to be usable afterward in place of the first jump table.

Since the alternative program is encrypted, even if the first nonvolatile memory is physically or electrically separated from the controller to illegally dump the alternative program, it is difficult to analyze the data. Furthermore, since the second jump table used for the execution of the processing program modified by the alternative program is stored in encryption in the first nonvolatile memory, even if the first nonvolatile memory can be physically or electrically separated from the controller to illegally dump the jump table, it is difficult to analyze its contents or tamper the contents for illegal purposes. Therefore, it becomes difficult to bring the controller into the execution of an illegal program by tampering the jump table, contributing to the prevention of such an illegal access as to enable an external reference to highly confidential data held within the controller.

When executing the encrypted alternative program transferred to the volatile memory, the data processor may decrypt the alternative program and store the decrypted alternative program in the volatile memory so as to be reusable afterward. A long wait is not required until data processing by the data processor is enabled after the exit from the reset processing. Since the alternative program once decrypted is held in the volatile memory so as to be reusable, there is no troublesomeness of decrypting the alternative program each time it is executed.

Effects obtained by typical disclosures of the invention will be described in brief as follows.

In technology for enabling the replacement of part of an operating program of a controller by a modified program on a nonvolatile memory, the present invention can contribute to prevention against tampering and leak of the program and data within the controller as well as the modified program on the nonvolatile memory.

In technology for enabling the replacement of part of an operating program of a controller by a modified program on a nonvolatile memory, the present invention can prevent replacement processing from causing long delays of operation start after reset processing even when the capacity of the modified program is large.

### BRIEF DESCRIPTION OF THE DRAWINGS

FIG. 1 is a block diagram showing a memory card according to an embodiment of the present invention.

FIG. 2 is a diagram illustrating how a processing program performs execution when neither a modification program module SMDLk nor a modification jump table STBL is stored in a prescribed area of a flash memory.

FIG. 3 is a diagram illustrating how data is written from a host device to a memory card.

FIG. 4 shows how operation is performed at power-on reset when a modification program module SMDLk and a modification jump table STBL are stored in prescribed areas of a flash memory.

FIG. 5 shows an execution form of the modification program module after the processing of FIG. 4.

FIG. 6 shows a processing procedure in which an encrypted modification program module is decrypted at the first execution, and held in RAM so as to be reusable afterward.

FIG. 7 shows an execution form of a processing program when a modification program module SMDLk and a modification jump table STBL are stored in prescribed areas of a flash memory.

FIG. 8 is a flowchart showing an operation procedure at power-on reset.

FIG. 9 is a diagram illustrating a modification jump table and a modification program module to which hash values are added.

FIG. 10 is a flowchart illustrating a data processing procedure by use of modification program modules.

FIG. 11 is a flowchart illustrating another example of a data processing procedure by use of modification program modules.

### DETAILED DESCRIPTION OF THE PREFERRED EMBODIMENTS

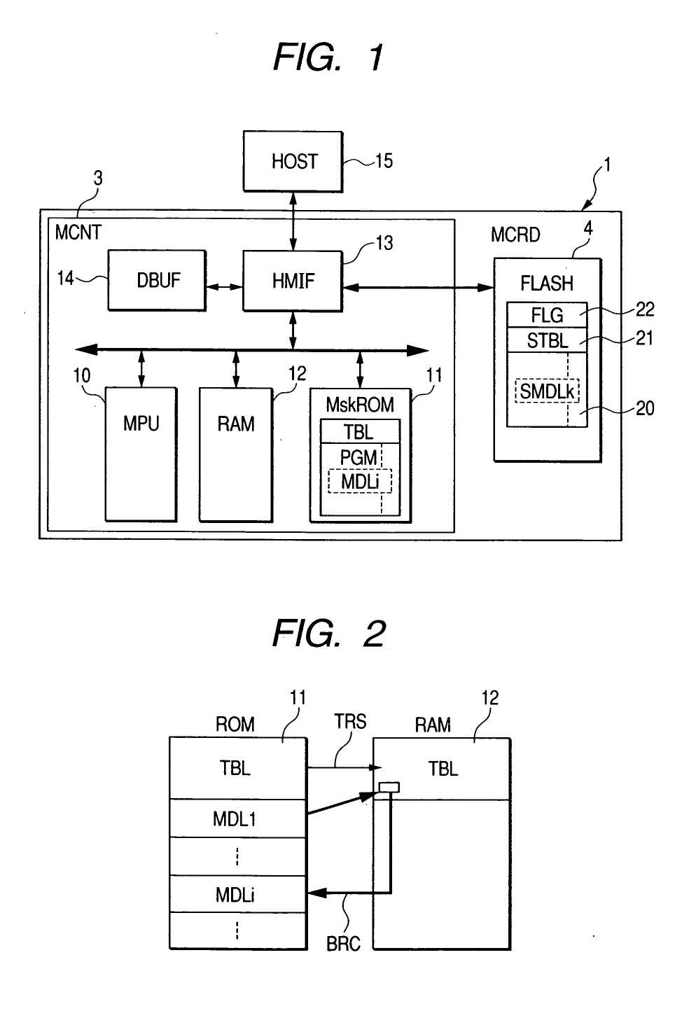

FIG. 1 shows a memory card according to an embodiment of the present invention. The memory card (MCRD) 1 includes a memory card controller (MCNT) 3 as a controller that performs data processing, and a flash memory (FLASH) 4 as a first nonvolatile memory which stores information so as to be rewritable under the control of the memory card controller 3, which are mounted on a card board. The flash memory 4 is constituted by one or plural flash memory chips. The memory card controller 3 is constituted by, e.g., a single chip. The memory card controller 3 includes: for example, a data processor (MPU) 10; a mask ROM (MskROM) 11 as an unrewritable second nonvolatile memory accessed by the data processor 10; a RAM (random access memory) 12 as a rewritable volatile memory accessed by the data processor 10; an interface circuit (HMIF) 13; and a data buffer (DBUF) 14.

The interface circuit 13 is interfaced with the host device (HOST) 15 and the flash memory 4. An interface from between the memory card controller 3 and the host device 15 is decided depending on the card specification of the memory card 1. Processing is performed in response to memory card commands complying with the card specification. For example, the memory card 1 complies with the specification of multimedia card (MultiMediaCard). MultiMediaCard is a registered trademark of InfineonTechnologiesAG. The host device 15 is interfaced with the flash memory 4 in the form of file access. In other words, the memory card controller 3 performs access control for the flash memory 4 as a file storage. The memory card controller 3, when a logical address for access (logical sector address) is specified by an access command fed by the host device 15, generates a physical address corresponding to it, and issues a memory access command complying with the specification of the flash memory 4 to the flash memory 4 to perform access control for the flash memory 4.

The mask ROM 11 includes a processing program PGM of the data processor 10 and a first jump table(initial jump table) TBL used when the processing program PGM is executed. The data processor 10 controls the host interface operation and the flash memory interface operation by executing the processing program PGM. The processing program PGM is constituted as a set of program modules MDLi (i=1 to n) modulated on a function basis, and the execution of a prescribed program module MDL1 is started immediately after reset is cleared. The processing program continues processing while jumping to other program modules MDLx within program modules MDLi. A table address used to refer to the jump table is described in a jump source program module. The start address information of a jump destination program module is held in an area referred to in the table address. The data processor 10 decodes a jump instruction, obtains address information from a jump table area of a table address described in an address field of the instruction, and switches a program execution address to an address indicated by the address information. As a result, the execution address changes to another program module specified in the program address.

The memory card controller 3 includes an FOF (farm on flash) function to for performing partial modifications on the processing program PGM. The FOF function will be explained.

The flash memory 4 includes: a storage area 20 of modification program modules SMDLk (k=1 to n number of arbitrary) as an encrypted alternative program to replace part of the processing program; a storage area 21 of an encrypted second jump table (modification jump table) STBL used when the processing program partially replaced by the modification program module SMDLk is executed; and a storage area 22 of flag information FLG for indicating whether the modification module SMDLk and the modification jump table STBL are stored in the areas 20 and 21.

FIG. 2 shows how the processing program performs execution when the modification program module SMDLk and the modification jump table STBL are not stored in the areas 20 and 21. At power-on reset, after an operation power voltage and a clock oscillation frequency become stable, the data processor 10 refers to the flag information FLG in the area 22, and when the modification program module SMDLk and the modification jump table STBL are not stored in the areas 20 and 21, transfers the initial jump table TBL on the ROM 11 to a prescribed storage area of a RAM 12 (TRS). Subsequently, the processing program, for example, to jump to another program module MDLi from the program module MDL1, refers to the initial jump table TBL on the RAM 12, and obtains the program address of the program modules MDLi to change an instruction execution order (BRC).

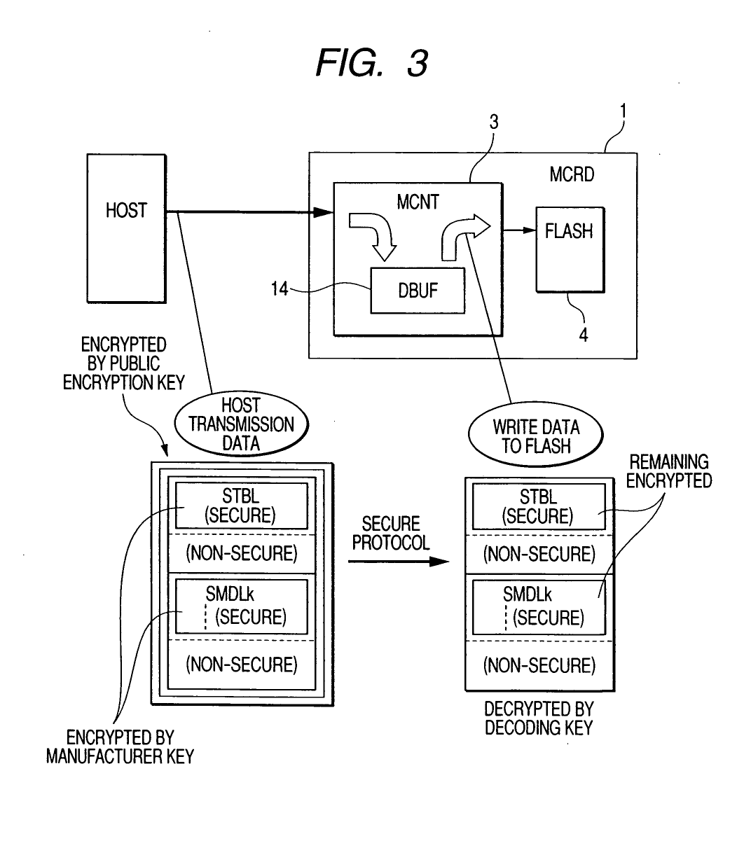

FIG. 3 shows how data is written from a host device 15 to a memory card 1. To safely transfer data from the host device 15 to the memory card 1, the transfer data is encrypted. A modification program SMDLk and a modification jump table STBL, which are used as secure modules, are encrypted using a manufacturer key and a public key of the memory card 1 before being transferred from the host device 15. Data and the like as other non-secure modules are encrypted by the public key of the memory card 1 before being transferred from the host device 15. The data transferred from the host device 15 is temporarily stored in a data buffer 14, and subsequently decrypted using a secret key of the memory card 1 by the data processor 10. Thereby, the secure module encrypted by the manufacturer key and the non-secure module of plain text can be taken out. The modification program SMDLk and the modification jump table STBL, which are used as secure modules, are stored in encryption in the flash memory 4. By this arrangement, even if the flash memory 4 is separated from the memory card 1 to illegally dump its storage information, it is difficult to analyze its contents. Since the modification jump table STBL is also encrypted, it is difficult to analyze and tamper the contents of the modification jump table STBL for illegal purposes. Therefore, an attempt can be curbed to tamper the modification jump table STBL to bring the data processor 10 into the execution of an illegal program, and such an illegal access as to enable an external reference to highly confidential data held within a memory card controller 3 by tampering the modification jump table STBL can be prevented. A program MDK (PM ER) that controls the writing of the modification program module SMDLk and the modification jump table STBL to the flash memory 4 is included in the processing program PGM as one program module MDLm.

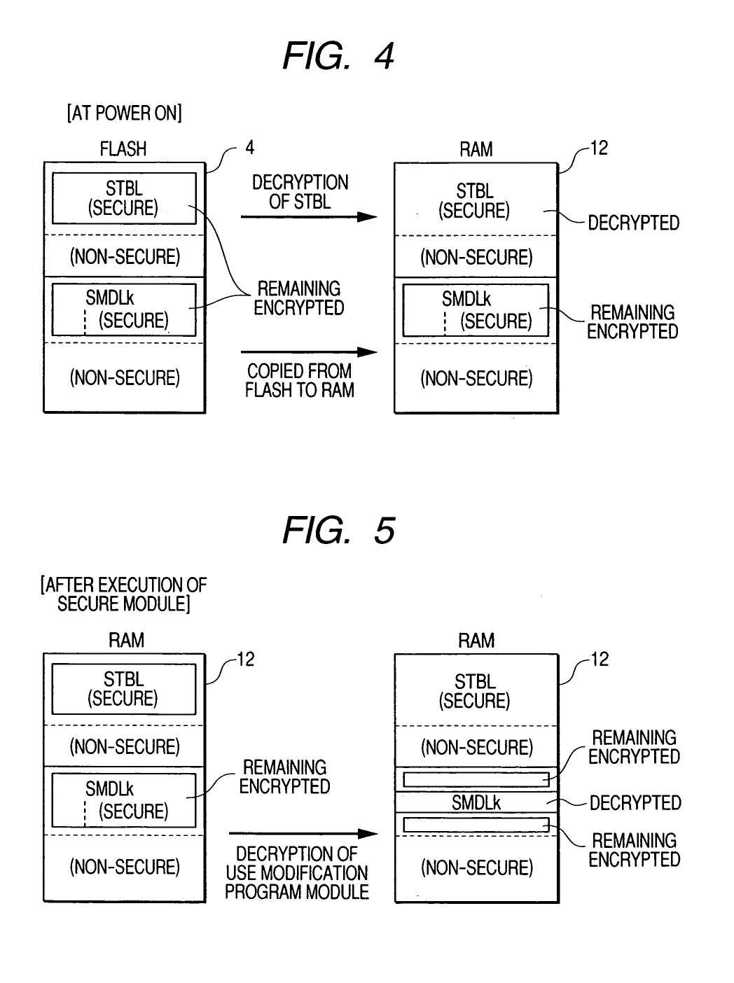

FIG. 4 shows how operation is performed at power-on reset when the modification program module SMDLk and the modification jump table STBL are stored in the areas 20 and 21. At power-on reset, after operation power voltage and clock oscillation frequency become stable, the data processor 10 refers to flag information FLG of the area 22, and when the modification program module SMDLk and the modification jump table STBL are stored in the areas 20 and 21, transfers the modification jump table STBL and the modification program module SMDLk on the flash memory 4 to a specified storage area of RAM 12. At this time, the data processor 10 decrypts the modification jump table STBL, and transfers the modification program module SMDLk remaining encrypted to the RAM 12. This is done to avoid a significant increase in processing time at power-on reset because decrypting the entire encrypted modification program module at a time would require a long processing time.

FIG. 5 shows an execution form of the modification program module after the processing of FIG. 4. The modification program module SMDLk transferred to the RAM 12 is decrypted at the first execution by the data processor 10. The decrypted modification program module SMDLk is held in the RAM 12 so as to be reusable afterward. The modification program module SMDLk transferred to the RAM is decrypted when it is actually executed. Accordingly, a long wait is not required until data processing by the data processor 10 is enabled after the exit from the reset processing. Since the alternative program once decrypted is held in the flash memory 4 so as to be reusable, there is no troublesomeness of decrypting the modification program module SMDLk each time it is executed.

Decryption processing for the modification program module SMDLk and the modification jump table STBL is performed by the data processor's 10 executing a decryption program MDL(DEC). The decryption program MDL(DEC) is included in the processing program PGM as one program module MDLh.

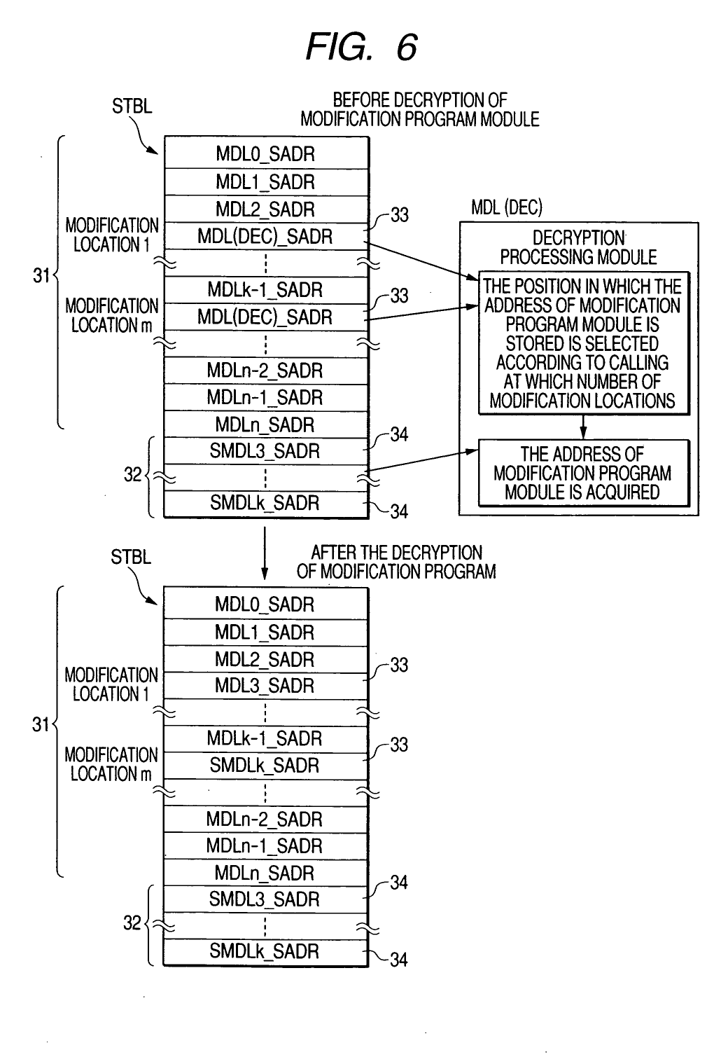

FIG. 6 shows a processing procedure in which an encrypted modification program module is decrypted at the first execution, and held in RAM so as to be reusable afterward. Here, the modification jump table STBL is rewritten to control the switching between the activation of the decryption processing program and the activation of the modification program module. Specifically, the modification jump table STBL includes a first table area 31 referred to in the processing program and a second table area 32 referred to in the decryption processing program MDL (DEC). The first table area 31 is allocated areas for holding the location address information (start address of program module) of program modules MDL0 to MDLn in the order of the program modules. MDLi_SADR denotes the start address of a program module MDLi. In a state in which decryption has been performed at power on and transfer has been made to RAM 14, in the first table area 31, first reference areas 33 allocated to refer to the location address information of the modification program module are stored with the start address MDL(DEC)_SADR of the decryption processing program MDL(DEC) as its location address information. The second table area 32 includes second reference areas 34 corresponding to the first reference areas 33. The second reference areas 34 are stored with the start address of the modification program module allocated to the corresponding first reference area 33 as its location address information. Specifically, in the modification jump table STBL before the decryption of the modification program module of FIG. 6, first reference areas 33 corresponding to modification locations 1 and 2 are stored with the start address MDL(DEC)_SADR of decryption processing program MDL(DEC). At this time, a second reference area 34 corresponding to a first reference area 33 of the modification location 1 is stored with the start address SMDL3_SADR of modification program module SMDL3. A second reference area 34 corresponding to a first reference area 33 of modification location m is stored with the start address SMDLk_SADR of modification program module SMDLk. Although not shown, a first reference area 33 has an identification code indicating the number of modification program modules counted from the start of the table when it is allocated to store the start address of a modification program module. The identification code is recognized by the decryption processing module MDL (DEC).

When the data processor 10 proceeds with program processing while referring to address information held in the first table area 31, if a decryption processing program is disposed at an address indicated by the address information, the decryption processing program uses an identification code coming with address information held in a first reference area 33 referred to at that time to acquire the location address of a modification program module held in a corresponding second reference area 34 in the second table area 32. For example, when a jump destination of a program jump instruction in a program module being currently executed by the data processor 10 is specified in the address of modification location 1 of the modification jump table STBL, the data processor 10 acquires the start address MDL(DEC)_SADR of decryption processing program module from the address and transitions to the execution of the decryption processing program module. At this time, the data processor 10 reads an identification code coming with address information held in a first reference area 33 referred to by an immediately preceding jump instruction. In the example of FIG. 6, a specified modification program module is a first one. According to the identification code, the data processor 10 acquires the location address SMDL3_SADR of a modification program module held in a second reference area 34 that corresponds to the first position of the second table area 32. The data processor 10 decrypts an encrypted modification program module specified in the address SMDL3_SADR. The decrypted modification program module is overwritten in the area specified in the same address SMDL3_SADR. Subsequently, the data processor 10 rewrites the location address information MDL(DEC)_SADR in the first reference area 33 having been used to refer to this decryption processing program module to the location address information SMDL3_SADR in corresponding second reference area 34. The state of the modification jump table STBL at the completion of the rewriting is shown as a state of modification program module decryption in FIG. 6. After the completion of the rewriting of the first reference area 33, the data processor returns to the processing before the jump to the decryption processing module to go to the start address SMDL3_SADR of the modification program module specified in the modification location 1. The above-mentioned decryption processing is, for each of modification program modules, performed only the first time that it is executed. Thereby, an encrypted modification program module can be decrypted at the-first execution timing, and subsequently, the decrypted modification program module can be directly executed.

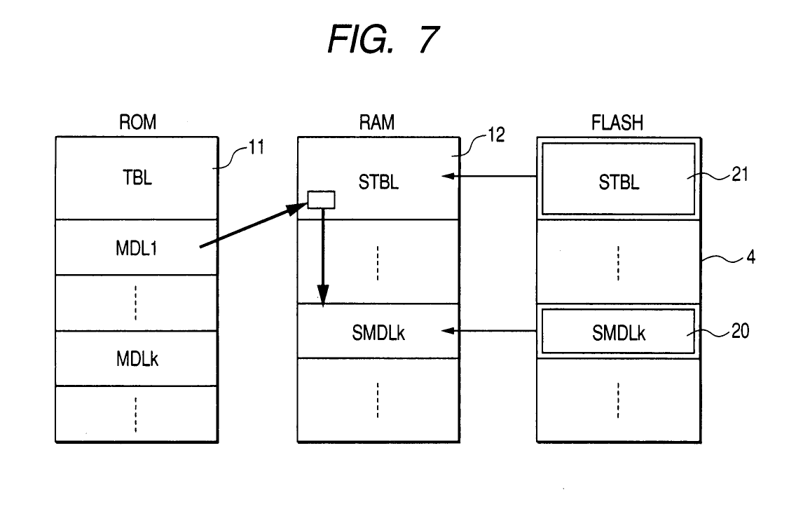

FIG. 7 shows the execution of a processing program when a modification program module SMDLk and a modification jump table STBL are stored in areas 20 and 21. A power-on reset, after operation power voltage and a clock oscillation frequency become stable, the data processor 10 refers to flag information FLG of the area 22, and when the modification program module SMDLk and the modification jump table STBL are stored in the areas 20 and 21, the modification program module SMDLk and the modification jump table STBL on the flash memory 4 are transferred to prescribed storage area of the RAM 12 and are decrypted as described previously. When e.g., program module MDL1 refers to a modification jump table STBL in subsequent execution of the processing program, if a jump destination is an address on the RAM 12, a modification program on the RAM 12 specified in the address, e.g., a modification program module SMDLk is executed.

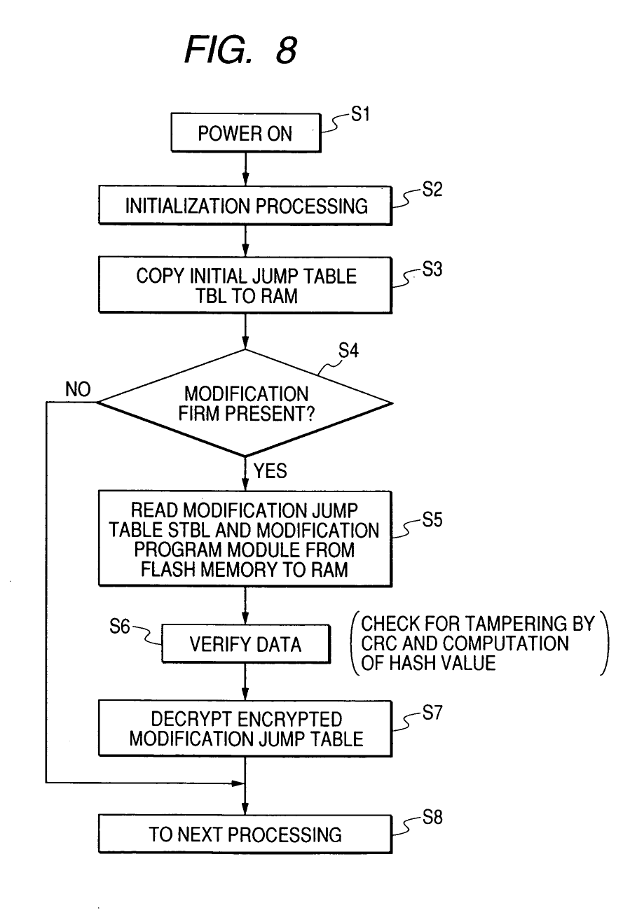

FIG. 8 is a flowchart showing an operation procedure at the power-on reset. When the power is turned on (S1), initialization processing (reset processing) is started (S2). When instruction execution by the data processor is enabled, the jump table TBL is transferred to the RAM 12 (S3). Whether modification firmware exists in the flash memory 4 is determined (S4). The modification firmware denotes modification jump table STBL and modification program module SMDLk. The flag FLG may be used for the determination. When the modification firmware exists, the modification jump table STBL and the modification program module SMDLk (5) are read into the RAM 12. Data verification is performed for the read modification jump table STBL and modification program module SMDLk (S6). For example, whether tampering has been made is checked by CRC (Cyclic Redundancy Check) code and computation of hash value. After the verification, the encrypted modification jump table STBL is decrypted (S7). After the decryption or when no modification firmware exists, the data processor proceeds to the next processing. Although not shown, as a result of the data verification, when tampering is suspected, error processing such as prohibition of the use of card may be performed.

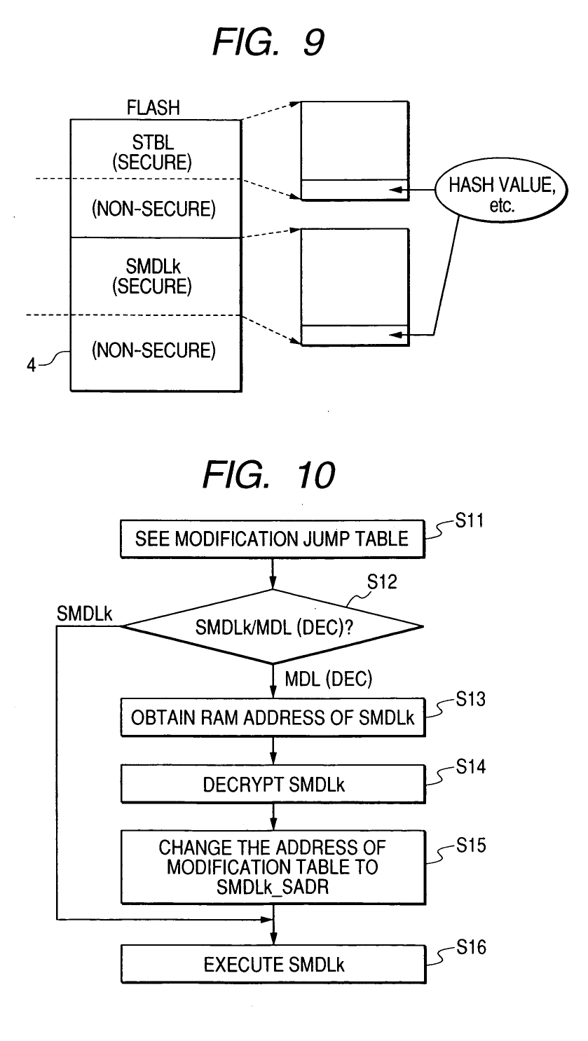

FIG. 9 shows a modification jump table and a modification program module to which hash values are added. Encrypted hash values may be added. A hash value of data concerned is calculated using a function at the time of the acquisition of a hash value, and compared with a hash value added to the data. If they differ, it may be determined that the data was tampered.

FIG. 10 shows a data processing procedure by use of modification program modules. When a jump is made to a different program module, the modification jump table is referred to (S11), and a jump destination address is obtained (S12). If a program of the jump destination address is a decryption processing program module MDL (DEC), as described previously, the location address of a modification program module SMDLk to be decrypted is obtained from area 34 (S13), a modification program module SMDLk obtained from there is decrypted, and the modification program module before the decryption is replaced by the modification program module after the decryption (S14). After that, the location address MDL(DEC)_SADR of the decryption processing program module stored in the modification jump table is changed to the location address SMDLk_SADR of the modification program module (S15), and the modification program module SMDLk is executed (S16). If a program of the jump destination address is a modification program module SMDLk in S12, the modification program module SMDLk may be executed (S16).

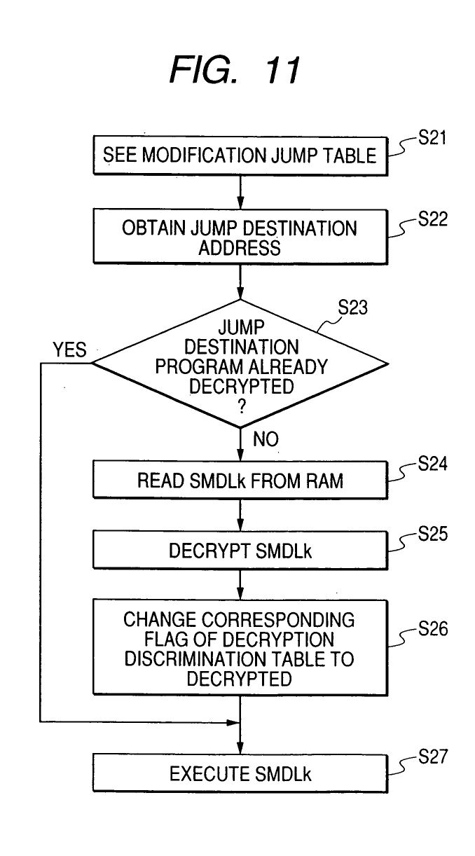

FIG. 11 shows another example of a data processing procedure by use of modification program modules. In this example, in an area specifying a jump destination address in the modification jump table, a jump destination address is specified whether decryption is incomplete or completed. Whether to decrypt a modification program module specified in the jump destination address is determined based on information held in a decryption discrimination table. The decryption discrimination table holds information indicating whether to perform description, corresponding to location address information of a modification program module.

When a jump is made to another program module, the modification jump table is referred to (S21), a jump destination address is obtained (S22), and whether a program of the jump destination has been already decrypted or not is determined using the decryption distinction table (S23). If the modification program module of the jump destination has not been decrypted, an encrypted modification program module SMDLk is read from the RAM 12 (S24) and decrypted, the modification program module before the decryption is replaced by the modification program module after the decryption (S25) a corresponding flag of the decryption distinction table on the replacing modification program module is changed to a code indicating the completion of decryption (S26), and the replacing modification program module SMDLk is executed (S27). If the modification program module of the jump destination has been already decrypted, decryption processing may be skipped to execute the modification program module SMDLk (S27).

According to the memory card described above, effects described below can be obtained.

Since the modification program module SMDLk is encrypted, even if the flash memory 4 is physically or electrically separated from the memory card controller 3 to illegally dump the modification program module SMDLk, it is difficult to analyze the data.

At power-on reset, the encrypted modification program module SMDLk, if present, is transferred from the flash memory 4 to the RAM 12, and decrypted when actually executed. Accordingly, a long wait is not required until data processing by the data processor 10 is enabled after the exit from the reset processing. Since the modification program module SMDLk once decrypted is held in the RAM 12 so as to be reusable, there is no troublesomeness of decrypting the modification program module SMDLk each time it is executed.

The modification program module SMDLk is decrypted the first time that the modification program module SMDLk transferred to the RAM 12 is executed. Meaningless signal processing is avoided when the operating power is turned off without even one execution of the modification program module SMDLk.

Since the modification jump table STBL used for execution of the processing program PGM modified by the modification program module SMDLk is stored in encryption in the flash memory 4, even if the flash memory 4 can be physically or electrically separated from the memory card controller 3 to illegally dump the modification jump table STBLk, it is difficult to analyze its contents or tamper the contents for illegal purposes. If the modification jump table could be tampered to bring the controller 3 into the execution of an illegal program, such an illegal access as to enable an external reference to highly confidential data within the controller 3 could be performed.

By referring to address information held in the first reference area 33 and executing the decryption processing program MDL (DEC) located in the address, the data processor acquires a modification program module SMDLk from an address of address information in the corresponding second reference area 34, decrypts the acquired modification program module SMDLk, and changes the address information held in the first reference area 33 to the address information held in the corresponding second area 34. By this processing, the modification program module SMDLk can be decrypted at its first execution timing, and afterward the decrypted modification program module SMDLk can be directly executed.

Hereinbefore, although the invention made by the inventors of the present invention has been described in detail based on the preferred embodiments, it goes without saying that the present invention is not limited to the preferred embodiments, but may be modified in various ways without changing the main purports of the present invention.

For example, a decrypted modification program module on RAM is not limited to being stored in the same address range as an encrypted modification program module. They may be located in different addresses from each other.

Address mapping of a second area corresponding to a first area is not limited to a method of determining the order of a modification program module on the modification jump table by offset from the start of the modification jump table.

The first nonvolatile memory is not limited to a flash memory. It may be a memory having other storage formats such as EEPROM.

The memory card interface is not limited to MMC. It may comply with other memory card specifications.

Decryption processing modules of a modification jump table and decryption processing modules of modification program modules may be wholly different, or may be partially common individual program modules having a standardized procedure control portion of decryption algorithm.

1. A memory apparatus comprising:
a controller that performs data processing;
a first nonvolatile memory that stores information so as to be rewritable under control of the controller; and
a second nonvolatile memory,
wherein the controller comprises: a data processor; an unrewritable second nonvolatile memory accessed by the data processor; and a rewritable volatile memory accessed by the data processor,
wherein the second nonvolatile memory holds a processing program of the data processor,
wherein the first nonvolatile memory includes a storage area of an encrypted alternative program to replace part of the processing program, and
wherein when performing a power-on reset operation, the data processor transfers the encrypted alternative program, if present, to the rewritable volatile memory, and after the transfer, when executing the encrypted alternative program, decrypts the encrypted alternative program and stores the decrypted alternative program in the volatile memory so as to be reusable afterward.

2. The memory apparatus according to claim 1,
wherein the encrypted alternative program is decrypted at the timing of its first execution after the transfer to the volatile memory.

3. The memory apparatus according to claim 1,
wherein the second nonvolatile memory includes a first jump table used when the processing program is executed, the first nonvolatile memory includes a storage area of a second jump table used when the processing program partially replaced by the decrypted alternative program is executed, and the storage area is used to store an encrypted second jump table, and
wherein, when the encrypted alternative program is transferred to the volatile memory after power-on reset being released, the data processor decrypts the second jump table and stores the decrypted second jump table in the volatile memory so as to be usable afterward in place of the first jump table.

4. The memory apparatus according to claim 3,
wherein the second nonvolatile memory has a write control program for writing the encrypted alternative program and the encrypted second jump table to the first nonvolatile memory.

5. The memory apparatus according to claim 3,
wherein the second nonvolatile memory has a decryption processing program for decrypting the encrypted alternative program and the encrypted second jump table.

6. The memory apparatus according to claim 5,
wherein the second jump table includes a first table area referred to in the processing program and a second table area referred to in the decryption processing program,
wherein the first table area includes a first reference area, in which a first allocated address of the decryption processing program is stored, used for storing a second allocated address of either the encrypted alternative program or the decrypted alternative program,
wherein the second table area includes a second reference area for storing a third allocated address of an area in the first reference area for storing the second allocated address information of either the encrypted alternative program or the decrypted alternative program, and
wherein, by referring to the first allocated address held in the first reference area and executing the decryption processing program fetched from the first allocated address, the data processor is capable of obtaining the encrypted alternative program from the third allocated address in the second reference area, decrypts the encrypted alternative program, and changes the second allocated address held in the first reference area to the third allocated address held in the second area.

7. The memory apparatus according to claim 6,
wherein the data processor can access the second nonvolatile memory and the volatile memory in byte units according to address signals, and can access the first nonvolatile memory in units of logical sectors according to address signals.

8. The memory apparatus according to claim 7,
wherein the controller has a host interface complying with a prescribed memory card standard.

9. A memory apparatus comprising: a controller that performs data processing; and a first nonvolatile memory that stores information so as to be rewritable under control of the controller,
wherein the controller comprises: a data processor; an unrewritable second nonvolatile memory accessed by the data processor; and a rewritable volatile memory accessed by the data processor,
wherein the second nonvolatile memory holds a processing program of the data processor and a first jump table used when the processing program is executed,
wherein the first nonvolatile memory includes a first storage area for storing an encrypted alternative program to replace part of the processing program and a second storage area for storing a encrypted second jump table for storing a first allocate address of the encrypted alternative program, and
wherein when performing a power-on reset operation, the data processor transfers the encrypted alternative program and the encrypted second jump table, if present, to the rewritable volatile memory, decrypts the encrypted second jump table, and stores a decrypted second jump table decrypted the encrypted second jump table in the rewritable volatile memory so as to be usable afterward in place of the first jump table.

10. The memory apparatus according to claim 9,
wherein the data processor, after transferring the encrypted alternative program to the volatile memory, decrypts the encrypted alternative program, stores a decrypted alternative program in the volatile memory so as to be reusable afterward, and then executes the decrypted alternative program fetched from the volatile memory.
